(19) United States
(12) Patent Application Publication
(10) Pub. No.: US 2025/0234746 A1
(43) Pub. Date: Jul. 17, 2025

(54) SUPPORT AND SUPPORT ASSEMBLY FOR DISPLAY MODULE, DISPLAY MODULE AND DISPLAY APPARATUS

(71) Applicant: BOE TECHNOLOGY GROUP CO., LTD., Beijing (CN)

(72) Inventors: Haoran WANG, Beijing (CN); Paoming TSAI, Beijing (CN)

(21) Appl. No.: 19/093,638

(22) Filed: Mar. 28, 2025

Related U.S. Application Data
(62) Division of application No. 17/923,038, filed on Nov. 3, 2022.

(51) Int. Cl. H10K 59/80; H10K 102/00

(52) U.S. Cl. CPC H10K 59/80; H10K 2102/311

(57) ABSTRACT

A support and a support assembly for a display module, a display module and a display apparatus, where the support includes: a first bending region; a plurality of second bending regions on two opposite sides of the first bending region, respectively; and a plurality of flat region, each of which is on a side of a corresponding second bending region away from the first bending region, a bending direction of each second bending region when bending is opposite to a bending direction of the first bending region when bending, at least one of the first bending region, the second bending region and the flat region is provided with a plurality of spring-hole groups arranged along a first direction, each spring-hole group includes a plurality of spring-holes arranged along a second direction, and the first direction is different from the second direction.

### CROSS-REFERENCE TO RELATED APPLICATION

This is a divisional application of a National Phase application Ser. No. 17/923,038 entitled “SUPPORT AND SUPPORT ASSEMBLY FOR DISPLAY MODULE, DISPLAY MODULE AND DISPLAY DEVICE” filed on Nov. 3, 2022, which is filed under 35 U.S.C. 371 as a national stage of PCT/CN2020/088996, filed May 7, 2020, the content of each of which is hereby incorporated by reference in its entirety.

### TECHNICAL FIELD

The present disclosure relates to the technical field of display apparatus, in particular to a support for a display module, a support assembly for a display module, a display module with the support for a display module or the support assembly for a display module, and a display apparatus with the display module.

### BACKGROUND

With the emergence of a complete machine in a folded form, various shapes of a bending region are increasingly explored. At present, the main shapes of the bending region mainly include two types, namely, a U shape and a water-drop shape. The water-drop shape is mainly used in a design for a complete machine with a display inward-folded. Compared with the U shape, the water-drop shape can provide a larger effective space for other components of the complete machine, thereby realizing the lightening and thinning of an inward-folded device.

The geometric design of the water-drop shape is more complex, and the distribution of strain and stress in a laminated structure of a flexible display module is also more complex. This shape itself puts higher demands on a design of a foldable display module. For example, since a main bending region and the water-drop-shaped bending region are substantially adjacent to each other and bent towards opposite directions, the stress is easily concentrated at an interface between the main bending region and the water-drop-shaped bending region, thereby causing a problem of glue failure of an adhesive layer of the flexible display module.

### SUMMARY

The present disclosure aims at solving at least one of the technical problems in related art. To this end, the present disclosure provides a support for a display module, through which a bending reliability of a local region can be realized, a stress in a bending region can be dispersed, a support performance of the bending region can be improved, and a recovery capability of the bending region after bending can be improved. Further, a horizontal stress concentration in a water-drop-shaped bending region can be effectively reduced while realizing the different bending radiuses and deformations in opposite bending directions, thereby solving the problem of glue failure of a laminated structure of the display module.

The present disclosure further provides a support assembly for a display module.

The present disclosure further provides a display module with the support for a display module or the support assembly for a display module.

The present disclosure further provides a display apparatus with the display module.

In a support for a display module according to an embodiment of a first aspect of the present disclosure, the display module is switchable between a folded state and an unfolded state, and the support includes: a first bending region; a plurality of second bending regions on two opposite sides of the first bending region, respectively; and a plurality of flat regions, each of which is on a side of one of the plurality of second bending regions away from the first bending region, where a bending direction of each of the plurality of second bending region is opposite to a bending direction of the first bending region when the display module is in the folded state, at least one of the first bending region, the second bending region and the flat region each is provided with a plurality of spring-hole groups arranged along a first direction, each of the plurality of spring-hole groups includes a plurality of spring-holes arranged along a second direction, and the first direction is different from the second direction.

In the support for a display module according to the embodiment of the present disclosure, through patterning for a local region, a bending reliability of the local region can be realized, a stress in the bending region can be dispersed, a support performance of the bending region can be improved, and a recovery capability of the bending region after bending can be improved. Further, through different designs for patterns and a matching design between the designs for patterns of two adjacent regions, a horizontal stress concentration in the water-drop-shaped bending region can be effectively reduced while realizing the different bending radiuses and deformations in opposite bending directions, thereby solving the problem of glue failure of a laminated structure of the display module.

In addition, the support for a display module according to the embodiment of the present disclosure further has the following additional technical features:

According to some embodiments of the present disclosure, a transition region is between the first bending region and the second bending region, and the transition region is a solid member.

According to some embodiments of the present disclosure, the first bending region, the second bending region and the flat region are a one-piece metal member.

According to some embodiments of the present disclosure, each of the plurality of spring-holes is a through hole.

According to some embodiments of the present disclosure, each of the plurality of spring-holes is filled with a flexible member.

In some specific embodiments of the present disclosure, a thickness of the flexible member is in a range of 0.001 mm to 0.5 mm.

According to some embodiments of the present disclosure, a shape of each of the plurality of spring-holes is any one of a circle, an oval, a rectangle, an arc-end rectangle, or a polygon.

A support assembly for a display module according to an embodiment of a second aspect of the present disclosure includes: the support for a display module according to the embodiment of the first aspect of the present disclosure; and a reinforcing member, where the reinforcing member is on a side of the support away from a flexible display panel of the display module, the reinforcing member includes a first reinforcing sheet and a second reinforcing sheet, both the first reinforcing sheet and the second reinforcing sheet are connected to a back surface of the support, a surface of the first reinforcing sheet close to the support and a surface of the second reinforcing sheet close to the support are in a same plane to support at least the first bending region when the display module is in the unfolded state, and the first reinforcing sheet and the second reinforcing sheet are opened and the surface of the first reinforcing sheet close to the support and the surface of the second reinforcing sheet close to the support are opposite to each other when the display module is in the folded state.

In the support assembly for a display module according to the embodiment of the present disclosure, through the above support for a display module, a bending reliability of the local region can be realized, a stress in the bending region can be dispersed, a support performance of the bending region can be improved, and a recovery capability of the bending region after bending can be improved. Further, a horizontal stress concentration in the water-drop-shaped bending region can be effectively reduced while realizing the different bending radiuses and deformations in opposite bending directions, thereby solving the problem of glue failure of a laminated structure of the display module. In addition, the first reinforcing sheet and the second reinforcing sheet not only can improve the flatness and the support performance of the bending region, but also can enhance an impact resistance of the bending region in the spreading state.

In addition, the support assembly for the display module according to the embodiment of the present disclosure also has the following additional technical features:

According to some embodiments of the present disclosure, the reinforcing member and the support are connected to each other at positions between the first bending region and the plurality of second bending regions.

According to some embodiments of the present disclosure, the first reinforcing sheet and the second reinforcing sheet are matched in shape when the display module is in the unfolded state.

In some embodiments of the present disclosure, a fit clearance between the first reinforcing sheet and the second reinforcing sheet is less than 10 mm when the display module is in the unfolded state.

In some specific embodiments of the present disclosure, the fit clearance between the first reinforcing sheet and the second reinforcing sheet is less than or equal to 2 mm when the display module is in the unfolded state.

According to some embodiments of the present disclosure, a thickness of the reinforcing member is in a range of 0.05 mm to 0.5 mm.

According to some embodiments of the present disclosure, a flexible buffer layer is provided between the reinforcing member and the support, and the flexible buffer layer corresponds to the first bending region in position.

According to some embodiments of the present disclosure, at least one of the first reinforcing sheet and the second reinforcing sheet includes a plurality of reinforcing sub-sheets sequentially connected together.

A display module according to an embodiment of a third aspect of the present disclosure includes: the support for a display module according to the embodiment of the first aspect of the present disclosure or the support assembly for a display module according to the embodiment of the second aspect of the present disclosure; and a flexible display panel, where the first bending region, the plurality of second bending regions and the plurality of flat regions of the support are attached to a backlight surface of the flexible display panel.

In the display module according to the embodiment of the present disclosure, through the support or the support assembly for a display module described above, a bending reliability of the local region can be realized, a stress in the bending region can be dispersed, a support performance of the bending region can be improved, and a recovery capability of the bending region after bending can be improved. Further, a horizontal stress concentration in the water-drop-shaped bending region can be effectively reduced while realizing the different bending radiuses and deformations in opposite bending directions, thereby solving the problem of glue failure of a laminated structure of the display module.

A display apparatus according to an embodiment of a third aspect of the present disclosure includes the display module according to the embodiment of the second aspect of the present disclosure.

In the display apparatus according to the embodiment of the present disclosure, through the above display module, a bending reliability of the local region can be realized, a stress in the bending region can be dispersed, a support performance of the bending region can be improved, and a recovery capability of the bending region after bending can be improved. Further, a horizontal stress concentration in the water-drop-shaped bending region can be effectively reduced while realizing the different bending radiuses and deformations in opposite bending directions, thereby solving the problem of glue failure of a laminated structure of the display module.

Additional aspects and advantages of the present disclosure will be set forth in part in the following description, will become apparent in part from the following description, or may be learned by practice of the present disclosure.

### BRIEF DESCRIPTION OF DRAWINGS

FIG. 1 is a schematic diagram of a structure of a display module according to an embodiment of the present disclosure;

FIG. 2 is a schematic diagram of a support for a display module in a bending state according to an embodiment of the present disclosure;

FIG. 3 is a schematic diagram of a support for a display module in a spreading state according to an embodiment of the present disclosure;

FIG. 4 is a schematic diagram of a support for a display module in a bending state according to an alternative embodiment of the present disclosure;

FIG. 5 is a schematic diagram of a structure of a part of a first bending region (a second bending region) according to an embodiment of the present disclosure;

FIG. 6 is a schematic diagram of a support assembly for a display module in a bending state according to an embodiment of the present disclosure;

FIG. 7 is a schematic diagram of a display module in a spreading state according to an embodiment of the present disclosure;

FIG. 8 is a schematic diagram of a display module in a spreading state according to an alternative embodiment of the present disclosure;

FIG. 9 is a schematic diagram of a reinforcing member in a spreading state according to an embodiment of the present disclosure;

FIG. 10 is a schematic diagram of a reinforcing member in a spreading state according to an alternative embodiment of the present disclosure;

FIG. 11 is a schematic diagram of a support assembly for a display module in a bending state according to an alternative embodiment of the present disclosure; and

FIG. 12 is a schematic diagram of a support for a display module in a spreading state according to a specific embodiment of the present disclosure.

### REFERENCE CHARACTERS

a display module 1, a support 10 for a display module, a spring-hole 11, a transition region 12, a first bending region 100, a second bending region 200, a flat region 300, a flexible display panel 20, a support assembly 30 for a display module, a reinforcing member 400, a reinforcing sub-sheet 401, a first reinforcing sheet 410, a second reinforcing sheet 420, a flexible buffer layer 500.

### DETAIL DESCRIPTION OF EMBODIMENTS

Embodiments of the present disclosure will be described in detail below, and examples of the embodiments are illustrated in the accompanying drawings, where same or similar reference numbers refer to the same or similar elements or elements having the same or similar functions throughout the description. The embodiments described below with reference to the accompanying drawings are exemplary only for explaining the present disclosure and are not to be construed as limiting the present disclosure.

A support 10 for a display module according to an embodiment of a first aspect of the present disclosure will be described below with reference to the accompanying drawings. The display module is switchable between a folded state and an unfolded state, and the support 10 is located at a backlight side of a flexible display panel of the display module.

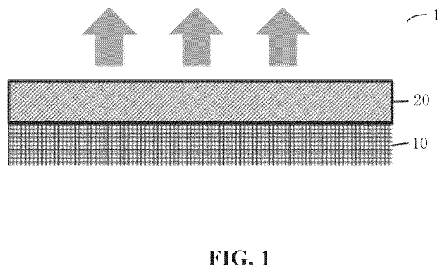

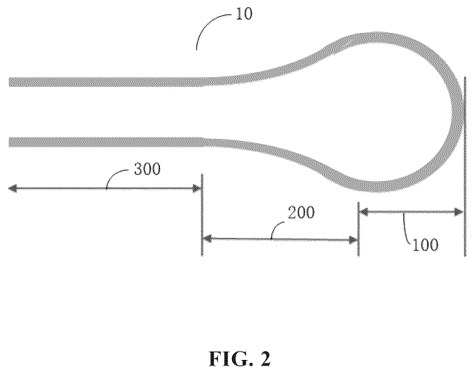

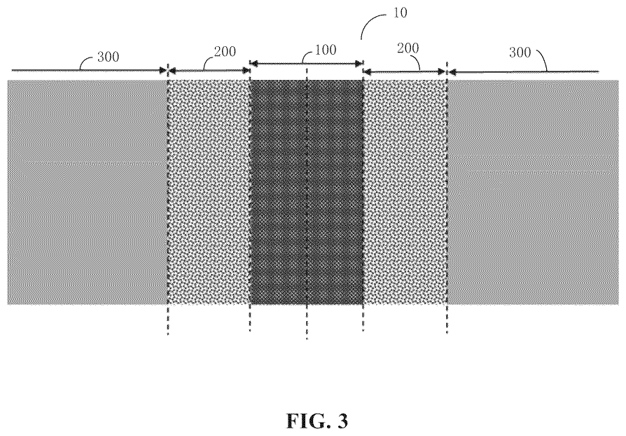

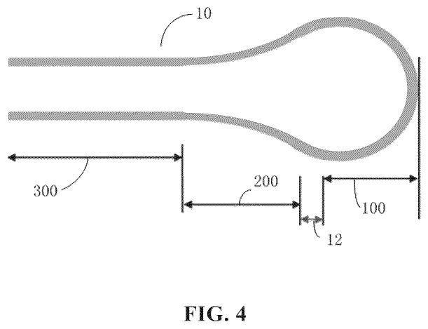

As shown in FIGS. 1 to 5 and 12, the support 10 for a display module according to an embodiment of the present disclosure includes a first bending region 100, a second bending region 200, and a flat region 300.

Specifically, the support 10 includes a plurality of second bending regions 200 distributed on two opposite sides of the first bending region 100, respectively. For example, the support 10 includes two second bending regions 200 located on a left side and a right side of the first bending region 100, respectively. The support 10 includes a plurality of flat regions 300, each of which is distributed on a side of a corresponding second bending region 200 away from the first bending region 100. For example, the support 10 includes two flat regions 300, one of the two flat regions 300 is located on a left side of the second bending region 200 on the left side, and the other of the two flat regions 300 is located on a right side of the second bending region 200 on the right side. It may be understood that the flat region 300 herein is flat relative to the bending region.

When the display module is in a folded state, a bending direction of the first bending region 100 is opposite to a bending direction of the second bending region 200. That is, a bending direction of the first bending region 100 during bending is opposite to a bending direction of the second bending region 200 during bending. For example, the first bending region 100 bends inward, and the second bending region 200 bends outward. Here, the term “inward” may be understood as an inside of the display module in the folded state, and the term “outward” may be understood as an outside of the display module in the folded state. For example, in a case where two second bending regions 200 and two flat regions 300 are provided, when the display module is in the folded state, the left and right sides of the first bending region 100 when not folded are opposite to each other in the up-down direction, the two second bending regions 200 are opposite to each other in the up-down direction, and the two flat regions 300 are opposite to each other in the up-down direction. A space surrounded by the first bending region 100, the two second bending regions 200 and the two flat regions 300 constitutes an internal space of the display module. At this time, a bending axis of the first bending region 100 is located inside the display module, and a bending axis of the second bending region 200 is located outside the display module. An arc top of a bending semicircle the first bending region 100 (corresponding to a main bending region) corresponds to a bending axis of the display module, and the second bending region 200 corresponds to a water-drop-shaped bending region.

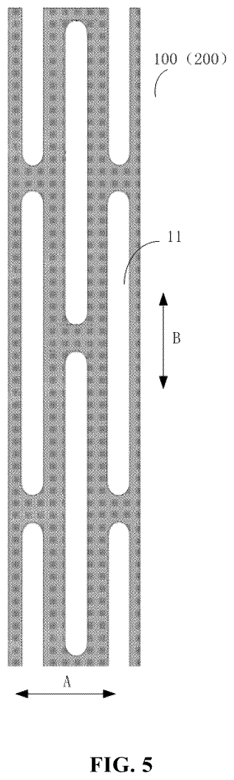

At least one of the first bending region 100, the second bending region 200 and the flat region 300 is provided with a plurality of groups of spring-holes 11, and the plurality of groups of spring-holes 11 are arranged along a first direction (for example, the direction A shown in FIG. 5). Each group includes a plurality of spring-holes 11, and the plurality of spring-holes 11 in each group are arranged along a second direction (for example, the direction B shown in FIG. 5). The first direction and the second direction are different from each other, and the first direction and the second direction may be perpendicular to each other or inclined with respect to each other. The spring-hole 11 is, for example, a through hole (penetrating through the support) or a half-through hole (for example, a groove). That is, one of the first bending region 100, the second bending region 200 and the flat region 300 may be provided with a plurality of spring-holes 11; alternatively, two of the first bending region 100, the second bending region 200 and the flat region 300 each may be provided with a plurality of spring-holes 11; alternatively, the first bending region 100, the second bending region 200 and the flat region 300 each may be provided with a plurality of spring-holes 11, and the plurality of spring-holes 11 may be arranged in a grid shape, to implement a patterned design. It may be understood that the design of patterned distribution of the spring-holes 11 in different regions may be the same as or different from each other.

Therefore, the support 10 for a display module uses a patterned design with different designs in different regions, and adapts to different requirements on support performance and bending resistance of the main bending region, the water-drop-shaped bending region and the flat region 300, and matches different bending radiuses and different geometric shapes.

In the support 10 for a display module according to the embodiment of the present disclosure, through patterning for the local region, a bending reliability of the local region can be realized, a stress in the bending region can be dispersed, a support performance of the bending region can be improved, and a recovery capability of the bending region after bending can be improved. Further, through different designs for patterns and a matching design between the designs for patterns of two adjacent regions, a horizontal stress concentration on the water-drop-shaped bending region can be effectively reduced while realizing the different bending radiuses and deformations in opposite bending directions, thereby solving the problem of glue failure of a laminated structure of the display module.

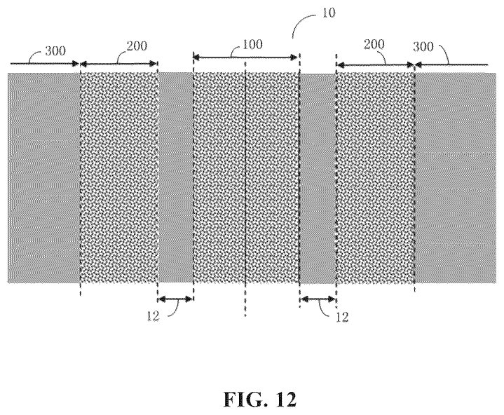

According to some embodiments of the present disclosure, as shown in FIG. 12, a transition region 12 is disposed between the first bending region 100 and the second bending region 200, and the transition region 12 is a solid member, so that the horizontal stress concentration of the water-drop-shaped bending region can be reduced more effectively while realizing different bending radiuses and the deformations in opposite bending directions, thereby solving the problem of the glue failure of the laminated structure of the display module. The shape, size and arrangement of the spring-holes 11 of the first bending region 100 are the same as those of the spring-holes 11 of the second bending region 200.

According to some embodiments of the present disclosure, the first bending region 100, the second bending region 200, and the flat region 300 may be a one-piece metal member, so that the support 10 has a simple structure, a high supporting strength, a strong recovery capability after bending, and the problems of stress concentration and glue failure of the laminated structure of the display module can be better solved. Here, the support 10 for a display module may be a hard metal such as stainless steel, titanium, magnesium, aluminum, or an alloy of other metals.

According to some embodiments of the present disclosure, the spring-hole 11 may be filled with a flexible member to reduce the local stress concentration in the hole. The flexible member may be made of a polymer material. For example, the flexible member is a rubber member, a silicone member, or a PU member.

In some specific embodiments of the present disclosure, a thickness of the flexible member is in a range of 0.001 mm to 0.5 mm, to ensure surface flatness while ensuring a certain elasticity.

According to some embodiments of the present disclosure, the shape of the spring-hole 11 may be any one of a circle, an oval, a rectangule, an arc-ended rectangule, or a polygon. The arc-end rectangular hole is an oblong hole, namely, the hole is in a strip shape, outlines of two ends of the hole each are in an arc shape, and an outline of a part between the two ends of the hole is in a straight line shape. It may be understood that the shapes of the spring-holes 11 in different regions may be the same as or different from each other, and the shapes of the spring-holes 11 in the same region may be the same as or different from each other, and one of ordinary skill in the art may make reasonable adjustments according to actual requirements on bending and supporting.

In a specific embodiment of the present disclosure, as shown in FIG. 5, the shape of the spring-hole 11 in the first bending region 100 is identical to the shape of the spring-hole 11 in the second bending region 200, and both are arc-ended rectangular through holes.

According to some embodiments of the present disclosure, the shapes of the first bending region 100, the second bending region 200 and the flat region 300 each are any one of a rectangle, an ellipse or a polygon. It may be understood that the shapes of the first bending region 100, the second bending region 200 and the flat region 300 may be the same as or different from each other, the shapes of the plurality of second bending regions 200 may be the same as or different from each other, and the shapes of the plurality of flat regions 300 may be the same as or different from each other.

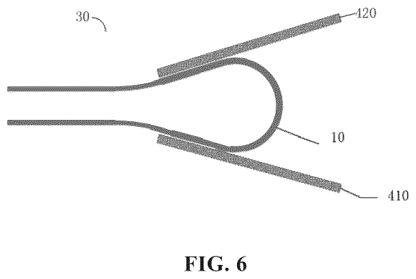

As shown in FIGS. 6 to 11, a support assembly 30 for a display module according to an embodiment of a second aspect of the present disclosure includes the support 10 for a display module according to the embodiment of the first aspect of the present disclosure and a reinforcing member 400.

Specifically, the reinforcing member 400 is located on a side of the support 10 away from the flexible display panel of the display module. That is, the support 10 is located between the reinforcing member 400 and the flexible display panel. The reinforcing member 400 includes a first reinforcing sheet 410 and a second reinforcing sheet 420, both of which are connected to a back surface of the support 10.

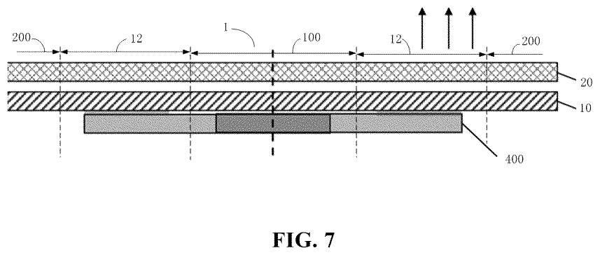

As shown in FIG. 7, when the display module is in the unfolded state, a surface of the first reinforcing sheet 410 close to the support 10 and a surface of the second reinforcing sheet 420 close to the support 10 are located in a same plane, to support at least the first bending region 100. Here, the term “to support at least the first bending region 100” means that, when the display module is in the unfolded state, the support 10 and the reinforcing member 400 are spread, and at this time, an orthographic projection of the first bending region 100 on a horizontal plane at least partially overlaps an orthographic projection of the reinforcing member 400 on the horizontal plane, so that the reinforcing member 400 supports the first bending region 100 in the spreading state. Alternatively, the reinforcing sheets may support a bending region other than the first bending region 100, which may be achieved by adjusting a connection position between the reinforcing sheets and the support 10.

As shown in FIG. 6, when the display module is in the folded state, the first reinforcing sheet 410 and the second reinforcing sheet 420 are opened, and the surface of the first reinforcing sheet 410 close to the support 10 and the surface of the second reinforcing sheet 420 close to the support 10 are opposite to each other. Here, the term “the surface of the first reinforcing sheet 410 close to the support 10 and the surface of the second reinforcing sheet 420 close to the support 10 are opposite to each other”, includes cases where the surface of the first reinforcing sheet 410 close to the support 10 and the surface of the second reinforcing sheet 420 close to the support 10 are directly opposite to each other; the surface of the first reinforcing sheet 410 close to the support 10 and the surface of the second reinforcing sheet 420 close to the support 10 are staggered; the surface of the first reinforcing sheet 410 close to the support 10 and the surface of the second reinforcing sheet 420 close to the support 10 are parallel to each other; and the surface of the first reinforcing sheet 410 close to the support 10 and the surface of the second reinforcing sheet 420 close to the support 10 are inclined with respect to each other. For example, during folding or unfolding, the first reinforcing sheet 410 and the second reinforcing sheet 420 are opened or spread as the support 10 moves, and the reinforcing sheets are opened when the support 10 is folded.

In the support assembly 30 for a display module according to the embodiment of the present disclosure, through the support 10 for a display module described above, a bending reliability of the local region can be realized, a stress in the bending region can be dispersed, a support performance of the bending region can be improved, and a recovery capability of the bending region after bending can be improved. Further, a horizontal stress concentration in the water-drop-shaped bending region can be effectively reduced while realizing the different bending radiuses and deformations in opposite bending directions, thereby solving the problem of glue failure of a laminated structure of the display module. In addition, the first reinforcing sheet 410 and the second reinforcing sheet 420 not only can improve the flatness and the support performance of the bending region, but also can enhance an impact resistance of the bending region in the spreading state.

According to some embodiments of the present disclosure, as shown in FIG. 7, the reinforcing member 400 and the support 10 are connected to each other at positions between the first bending region 100 and the second bending regions 200. That is, the first reinforcing sheet 410 and the support 10 are connected to each other at a position between the first bending region 100 and a corresponding second bending region 200, and/or the second reinforcing sheet 420 and the support 10 are connected to each other at a position between the first bending region 100 and a corresponding second bending region 200. For example, the position at which the first reinforcing sheet 410 and the support 10 are connected to each other and the position at which the second reinforcing sheet 420 and the support 10 are connected to each other are disposed on two opposite sides of the first bending region 100, respectively. In a case where the transition region 12 is disposed between the first bending region 100 and each second bending region 200, the first reinforcing sheet 410 and the second reinforcing sheet 420 may be connected to the transition regions 12 on two sides of the first bending region 100, respectively, to supplement the support performance and impact resistance of the bending region.

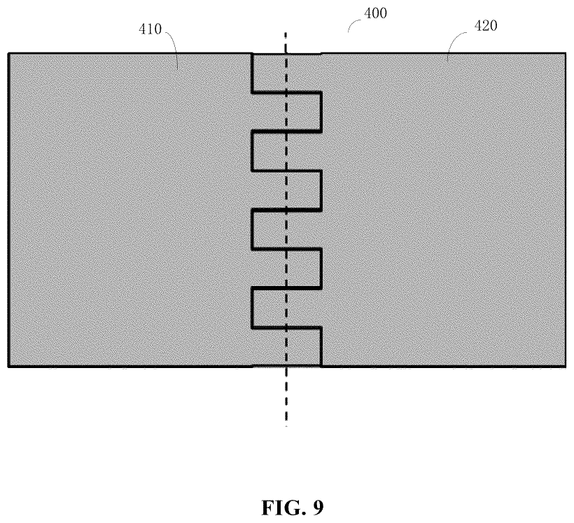

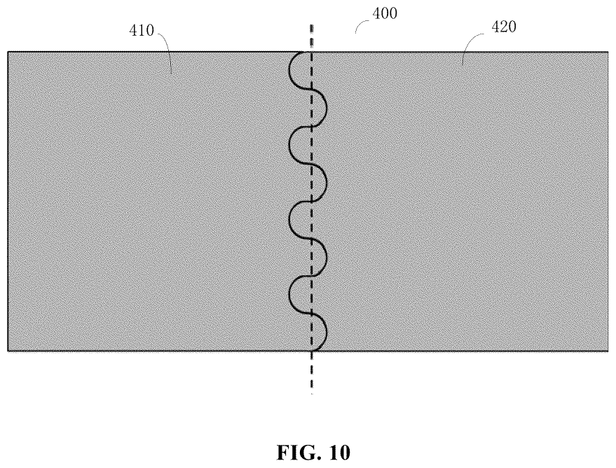

According to some embodiments of the present disclosure, as shown in FIGS. 9 and 10, the first reinforcing sheet 410 and the second reinforcing sheet 420 are matched in shape when the display module is in the unfolded state. That is, the first reinforcing sheet 410 and the second reinforcing sheet 420 are spliced, so that folding and unfolding are facilitated, and the improvement of the support performance and impact resistance are facilitated.

In some embodiments of the present disclosure, a fit clearance between the first reinforcing sheet 410 and the second reinforcing sheet 420 is less than 10 mm when the display module is in the unfolded state, to ensure the support performance and the impact resistance. Further, the fit clearance between the first reinforcing sheet 410 and the second reinforcing sheet 420 is less than or equal to 2 mm when the display module is in the unfolded state.

According to some embodiments of the present disclosure, each of the first reinforcing sheet 410 and the second reinforcing sheet 420 has a thickness in a range of 0.05 mm to 0.5 mm, to ensure sufficient support performance and reduce a storage space occupied when folded.

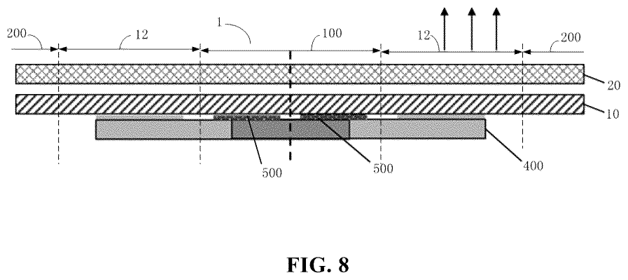

According to some embodiments of the present disclosure, as shown in FIG. 8, a flexible buffer layer 500 is disposed between the reinforcing member 400 and the support 10. That is, the flexible buffer layer 500 is provided between at least one of the first reinforcing sheet 410 and the second reinforcing sheet 420 and the support 10. For example, the flexible buffer layers 500 are disposed between the first reinforcing sheet 410 and the support 10 and between the second reinforcing sheet 420 and the support 10, respectively. The flexible buffer layers 500 are fixed to the back surface of the support 10, and the flexible buffer layers 500 correspond to the first bending region 100 in position, to supplement a gap between the reinforcing member 400 and the support 10 and thus, improve the reliability.

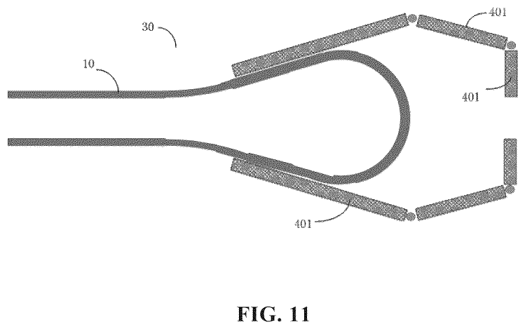

According to some embodiments of the present disclosure, as shown in FIG. 11, at least one of the first reinforcing sheet 410 and the second reinforcing sheet 420 is formed by a plurality of reinforcing sub-sheets 401 sequentially connected together. It may be understood that the plurality of reinforcing sub-sheets 401 may be connected to each other through a fixing shaft. For example, each of the first reinforcing sheet 410 and the second reinforcing sheet 420 is formed by sequentially connecting a plurality of reinforcing sub-sheets 401 together, so that a smaller storage space may be provided in the folded state. In some specific embodiments of the present disclosure, the reinforcing member 400 and the support 10 each may be a metal member, such as a stainless steel member, an aluminum alloy member, a magnesium alloy member, or a titanium alloy member. The reinforcing member 400 and the support 10 may be fixed together by adhering through an adhesive layer, or by metal riveting, or by welding.

A display module 1 according to an embodiment of a third aspect of the present disclosure includes the support 10 for a display module according to the embodiment of the first aspect of the present disclosure and a flexible display panel 20. Alternatively, the display module 1 according to the embodiment of the third aspect of the present disclosure includes the support assembly 30 for a display module according to the embodiment of the second aspect of the present disclosure and the flexible display panel 20.

Specifically, the flexible display panel 20 has a top emission structure, and the first bending region 100, the second bending regions 200 and the flat regions 300 are attached to a backlight surface (non-light emitting surface) of the flexible display panel 20. The flexible display panel 20 is, for example, an OLED panel. Thus, the water-drop-shaped bending structure is subjected to a patterned design with different designs in different regions (the main bending region, the water-drop-shaped bending regions, and the flat regions 300), to match the bending states of different regions.

In the display module 1 according to the embodiment of the present disclosure, through the above support 10 for a display module, a bending reliability of the local region can be realized, a stress in the bending region can be dispersed, a support performance of the bending region can be improved, and a recovery capability of the bending region after bending can be improved. Further, a horizontal stress concentration in the water-drop-shaped bending region can be effectively reduced while realizing the different bending radiuses and deformations in opposite bending directions, thereby solving the problem of glue failure of a laminated structure of the display module.

Other configurations and operations of the display module 1 according to the embodiment of the present disclosure are known to one of ordinary skill in the art and will not be described in detail herein.

A display apparatus according to an embodiment of a fourth aspect of the present disclosure includes the display module 1 according to the embodiment of the third aspect of the present disclosure.

In the display apparatus according to the embodiment of the present disclosure, through the above display module 1, a bending reliability of the local region can be realized, a stress in the bending region can be dispersed, a support performance of the bending region can be improved, and a recovery capability of the bending region after bending can be improved. Further, a horizontal stress concentration in the water-drop-shaped bending region can be effectively reduced while realizing the different bending radiuses and deformations in opposite bending directions, thereby solving the problem of glue failure of a laminated structure of the display module.

Other configurations and operations of the display apparatus according to the

embodiment of the present disclosure are known to one of ordinary skill in the art and will not be described in detail herein.

In the description of the present disclosure, it should be understood that the terms “central,” “longitudinal,” “transverse,” “length,” “width,” “thickness,” “up,” “down,” “front,” “rear,” “left,” “right,” “vertical,” “horizontal,” “top,” “bottom,” “inner,” “outer,” “clockwise,” “counterclockwise,” “axial,” “radial,” “circumferential,” and the like indicate the orientations and positional relationships in the drawings for convenience in describing the present disclosure and to simplify the description only, but are not intended to indicate or imply that the device or element so referred to must have a particular orientation, be constructed and operated in a particular orientation, and are not to be construed as limiting the present disclosure.

Furthermore, the terms “first” and “second” are used for descriptive purposes only and should not to be construed as indicating or implying relative importance or implicitly indicating the number of technical features indicated. Thus, a feature defined by the term “first” or “second” may explicitly or implicitly include one or more features. In the description of the present disclosure, the term “a plurality of” means two or more unless specifically limited otherwise.

In the description of the present disclosure, “a first feature” and “a second feature” may include one or more of the features. The first feature being “on” or “under” the second feature may include the first and second features being in direct contact with each other, or the first and second features not being in direct contact with each other but being in contact with each other through another feature therebetween. The first feature being “over,” “above,” or “on top of” the second feature includes the first feature being directly above and obliquely above the second feature, or simply indicates that the first feature is higher than the second feature.

It should be noted that unless explicitly stated or limited otherwise, the terms “mounted,” “coupled” and “connected” in the description of the present disclosure should be construed broadly and may for example be fixedly connected, detachably connected or integrally connected; may be mechanically or electrically connected; may be directly connected or indirectly connected through intervening media, or may be an internal connection between two elements. The specific meanings of the above terms in the present disclosure may be understood in a specific case to one of ordinary skill in the art.

In the description of this specification, the description with reference to the term “one embodiment”, “some embodiments”, “a specific embodiment”, “an example”, or “some examples” or the like means that a specific feature, structure, material, or characteristic described in connection with the embodiment or example is included in at least one embodiment or example of the present disclosure. In this specification, schematic representations of the above terms do not necessarily refer to the same embodiment or example. Furthermore, the specific feature, structure, material, or characteristic described may be combined in a suitable manner in any one or more embodiments or examples.

While the embodiment of the present disclosure has been shown and described, it will be understood by one of ordinary skill in the art that numerous changes, modifications, substitutions and variations may be made to the embodiment without departing from the principle and spirit of the present disclosure, the scope of the present disclosure is defined by the claims and their equivalents.

What is claimed is:

1. A support for a display module, wherein the display module is switchable between a folded state and an unfolded state, and the support comprises:
a first bending region;
a plurality of second bending regions on two opposite sides of the first bending region, respectively; and
a plurality of flat regions, each of which is on a side of one of the plurality of second bending regions away from the first bending region,
wherein a bending direction of each of the plurality of second bending regions is opposite to a bending direction of the first bending region when the display module is in the folded state, at least one of the first bending region, the second bending region and the flat region each is provided with a plurality of spring-hole groups arranged along a first direction, each of the plurality of spring-hole groups comprises a plurality of spring-holes arranged along a second direction, and the first direction is different from the second direction,
wherein the support further comprises a transition region between the first bending region and the second bending region, wherein the transition region is a solid member.

2. A support assembly for a display module, comprising:
the support according to claim 1; and
a reinforcing member, wherein the reinforcing member is on a side of the support away from a flexible display panel of the display module, the reinforcing member comprises a first reinforcing sheet and a second reinforcing sheet, both the first reinforcing sheet and the second reinforcing sheet are connected to a back surface of the support, a surface of the first reinforcing sheet close to the support and a surface of the second reinforcing sheet close to the support are in a same plane to support at least the first bending region when the display module is in the unfolded state, and the first reinforcing sheet and the second reinforcing sheet are opened and the surface of the first reinforcing sheet close to the support and the surface of the second reinforcing sheet close to the support are opposite to each other when the display module is in the folded state.

3. The support assembly according to claim 2, wherein the reinforcing member and the support are connected to each other at positions between the first bending region and the plurality of second bending regions.

4. The support assembly according to claim 2, wherein the first reinforcing sheet and the second reinforcing sheet are matched in shape when the display module is in the unfolded state.

5. The support assembly according to claim 4, wherein a fit clearance between the first reinforcing sheet and the second reinforcing sheet is less than 10 mm when the display module is in the unfolded state.

6. The support assembly according to claim 5, wherein the fit clearance between the first reinforcing sheet and the second reinforcing sheet is less than or equal to 2 mm when the display module is in the unfolded state.

7. The support assembly according to claim 2, wherein a thickness of the reinforcing member is in a range of 0.05 mm to 0.5 mm.

8. The support assembly according to claim 2, further comprising a flexible buffer layer between the reinforcing member and the support, wherein the flexible buffer layer corresponds to the first bending region in position.

9. The support assembly according to claim 2, wherein at least one of the first reinforcing sheet and the second reinforcing sheet comprises a plurality of reinforcing sub-sheets sequentially connected together.

10. A display module, comprising:
the support according to claim 1; and
a flexible display panel, wherein the first bending region, the plurality of second bending regions and the plurality of flat regions of the support are attached to a backlight surface of the flexible display panel.

11. A display apparatus, comprising the display module according to claim 10.

12. A display module, comprising:
the support assembly according to claim 2; and
a flexible display panel, wherein the first bending region, the plurality of second bending regions and the plurality of flat regions of the support are attached to a backlight surface of the flexible display panel.

13. A display apparatus, comprising the display module according to claim 12.
